(19) United States
(12) Patent Application Publication
(10) Pub. No.: US 2010/0075191 A1
(43) Pub. Date: Mar. 25, 2010

(54) Textured solid oxide fuel cell having reduced polarization losses

(76) Inventors: David E. Nelson, Independence Township, MI (US); Juston L. Hussong, Cincinnati, OH (US); Daniel R. Confer, Flushing, MI (US); Russell H. Bosch, Gaines, MI (US)

Correspondence Address: DELPHI TECHNOLOGIES, INC;LEGAL STAFF - M/C 483-400-402, 5725 DELPHI DRIVE, PO BOX 5052, TROY, MI, 48007, US

(21) Appl. No.: 12/284,500

(22) Filed: Sep. 23, 2008

(51) Int. Cl. H01M 8/10; B05D 5/12; B05D 1/04; C23C 16/48

(52) U.S. Cl. 429/31; 429/30; 427/115; 427/458; 427/585

(57) ABSTRACT

An improved SOFC including textural features pressed into a structural anode and electrolyte bi-layer laminate to increase the active surface area of the finished fuel cell anode and cathode. This arrangement reduces current losses from ohmic, concentration, and activation polarization. In a presently preferred embodiment, an array of dimples is formed during manufacture of the bi-layer laminate by isostatically pressing an array of steel balls against the laminate before firing thereof. The dimples or other features may be varied in depth and spacing as may be desired to optimize gas flow through the SOFC and fuel efficiency thereof. The array may be close-spaced or not and may have any desired geometric packing form, including rectangular and hexagonal.

### RELATIONSHIP TO GOVERNMENT CONTRACTS

The present invention was supported in part by a US Government Contract, No. DE-FC26-02NT41246. The United States Government may have rights in the present invention.

### TECHNICAL FIELD

The present invention relates to fuel cells; more particularly, to an anode-supported solid oxide fuel cell; and most particularly, to such a fuel cell wherein the surface area of the fuel cell that is exposed to the cell's reactant gases is increased by texturing to reduce voltage loss from polarization.

### BACKGROUND OF THE INVENTION

Fuel cells for combining hydrogen and oxygen to produce electricity are well known. A known class of fuel cells includes a solid-oxide electrolyte layer through which oxygen anions migrate; such fuel cells are referred to in the art as “solid-oxide” fuel cells (SOFCs). A prior art SOFC subassembly comprises a ceramic solid-oxide electrolyte layer and a cathode layer coated onto a relatively thick, structurally-significant anode element. This arrangement is known in the art as a “planar anode-supported solid oxide fuel cell”. Such a prior art SOFC has a nominally flat profile, with no feature departing substantially from its flat profile.

An SOFC is typically fueled by “reformate” gas, which is the effluent from a catalytic liquid or gaseous hydrocarbon oxidizing reformer, also referred to herein as “fuel gas”. Reformate typically includes amounts of carbon monoxide (CO) as fuel in addition to molecular hydrogen.

A complete fuel cell stack assembly includes fuel cell subassemblies and a plurality of components known in the art as interconnects, which electrically connect the individual fuel cell subassemblies in series. Typically, the interconnects include a conductive foam, weave, or mesh disposed adjacent the anodes and cathodes of the subassemblies.

SOFCs are subject to polarization, a voltage loss which is a function of current density. There are three key types of polarization: ohmic polarization; concentration polarization; and activation polarization.

Ohmic polarization is related to the resistivities of the various cell layers, such as anode, active anode, electrolyte, interlayer, cathode, conductive layer, and interconnects, multiplied by their thickness. Another ohmic-related issue is contact resistance.

Concentration polarization is related to the ability to transport reacting species. Transport of gaseous species is largely through binary diffusion, wherein diffusivity is a function of the binary diffusion of reactant species such as H₂, O₂, and H₂O, and microstructural parameters.

Activation polarization is related to the pace of the reaction and is affected mainly by material properties, microstructure, temperature, atmosphere, and current density. Prior art SOFC designs are limited by these three types of polarization losses. What is needed in the art is a way to reduce polarization losses by reducing current density without loss of net power.

Prior art SOFC designs utilize a relatively thick planar anode layer in order to provide sufficient mechanical strength to the fuel cell. However, the anode is comprised of NiO and yttrium-stabilized zirconia (YSZ), each of which is relatively expensive. Indeed, this “thick” structural anode layer contributes significantly to the overall cost of a prior art SOFC cell. What is needed in the art is a way to reduce the thickness of the anode layer without sacrificing structural strength and integrity.

Prior art SOFCs utilize a repeating unit design including interconnects to conduct electricity between cells and to enable fuel or air flow to the diffusion areas of the individual cells. Typically, a silver-coated Kanthal mesh is used for the current interconnect material on the cathode side, with a silver/palladium paste being used at the interconnect/cell connections. Silver-coated Kanthal and silver/palladium paste are expensive materials. What is needed in the art is a way to reduce or eliminate the use of these materials in a fuel cell stack.

It is a principal object of the present invention to improve the performance of an SOFC by reducing polarization.

It is a further object of the invention to reduce the manufacturing cost of an SOFC by reducing the cost of the anode and interconnects.

### SUMMARY OF THE INVENTION

Briefly described, an improved SOFC includes textural surface features formed in a structural anode and electrolyte bi-layer laminate to increase the active surface areas of the anode and cathode. This arrangement reduces current losses from ohmic, concentration, and activation polarization. In one aspect of the invention, an array of dimples may be formed during manufacture of the bi-layer laminate by isostatically pressing an array of shaped balls, such as spherical, against the laminate before firing thereof. The dimples or other features may be varied in depth, height, and/or spacing as may be desired to optimize gas flow through the SOFC and fuel utilization thereof. The array may be close-spaced or not and may have any desired geometric packing form, including rectangular and hexagonal.

### BRIEF DESCRIPTION OF THE DRAWINGS

The present invention will now be described, by way of example, with reference to the accompanying drawings, in which:

FIG. 1 is an elevational cross-sectional view of a prior art solid oxide fuel cell;

FIG. 2 is a plan view of a first embodiment of an SOFC having increased surface area in accordance with the present invention;

FIG. 3 is a plan view of a single spherical feature as shown in FIG. 2;

FIG. 4 is a plan view of a second embodiment of an SOFC having increased surface area, showing a hexagonally close-spaced array which is the theoretical limit;

FIG. 5 is a plan view of a third embodiment of an SOFC having increased surface area, showing a practical hexagonal array formed from partial hemispherical R insertion of a hexagonal close-spaced ball indenter array onto a bilayer;

FIG. 6 is a table showing increased fuel cell surface area as a function of sphere diameter, depth, and bi-layer laminate thickness;

FIG. 7 is an elevational cross-sectional view of a portion of a featured backing plate for forming a featured fuel cell in accordance with the present invention;

FIG. 8 is a plan view of a fourth embodiment of an SOFC having increased surface area wherein a large-size dimple pattern is combined with smaller interstitial dimples;

FIG. 9 is a plan view of a fifth embodiment of an SOFC having increased surface area wherein dimple size varies in the gas flow direction;

FIG. 10 is an elevational cross-sectional view of a portion of a featured backing plate for forming a featured bi-layer laminate, showing identical dimple heights for varying diameters of dimples, as could be used for forming the dimple patterns shown in FIGS. 8 and 9;

FIG. 11 is an elevational cross-sectional view of a portion of a featured backing plate for forming a featured bi-layer laminate having non-close-spaced dimple features of differing radius and equal depth, also having flat regions between the dimples;

FIG. 12 is an elevational cross-sectional view of a portion of a featured backing plate for forming a featured bi-layer laminate having close-spaced dimple features of differing radius and equal depth; and

FIG. 13 is an elevational cross-sectional view of a portion of a featured backing plate for forming a featured bi-layer laminate having a sinusoidally-varying surface.

Corresponding reference characters indicate corresponding parts throughout the several views. The exemplifications set out herein illustrate currently-preferred embodiments of the invention, and such exemplifications are not to be construed as limiting the scope of the invention in any manner.

### DESCRIPTION OF THE PREFERRED EMBODIMENTS

Referring to FIG. 1, a prior art solid oxide fuel cell 10 comprises a structural anode layer 12, typically formed of three individual layers 12a,12b,12c laminated together; an electrolyte layer 14 laminated to anode layer 12; and a cathode layer 16 attached to electrolyte layer 14. Prior art fuel cell 10 is substantially planar and unfeatured along the gas-exchange surfaces 20,22. An intermediate stage in manufacture before addition of cathode layer 16 is a two-layer sub-assembly 18, also referred to herein as a bi-layer laminate, comprising anode layer 12 and electrolyte layer 14. During manufacturing, bi-layer laminate 18 typically requires exposure to high heat (“firing”) to be converted from a “green” or un-fired state to a “cured” or fired state. The present invention is directed to methods for increasing the surface area of anode layer 12 and cathode layer 16 while in the green state to reduce polarization losses in a finished fuel cell.

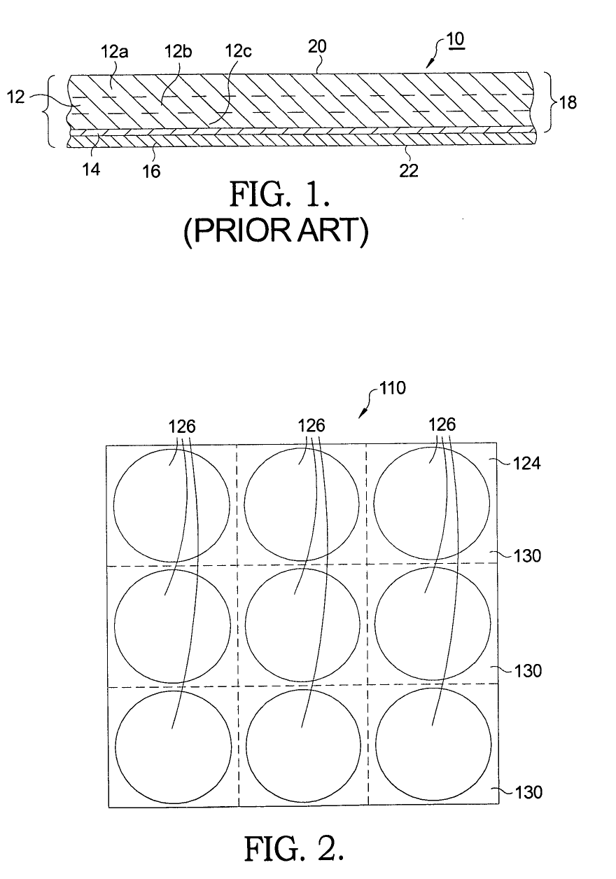

Referring to FIG. 2, a plan view is shown of a portion of a textured anode-supported solid oxide fuel cell 110 in accordance with the present invention. In the macro sense, a planar shape is maintained. However, on the micro level, the surface of the anode/electrolyte b-layer 18 includes, as an example, an array 124 of dimples 126 formed as described below, creating additional surface area not present in prior art planar SOFC cell 10 which in turn limits polarization losses. The dimple structure also provides mechanical stiffness to the cell and thereby allows a reduction in anode thickness without loss of structural strength. The increased surface area shows benefit against all polarization losses, as a result of increased surface area for transport and reaction per unit of cell area or stack volume. The increased surface area of the dimpled cell 110 allows the cells to achieve target power level at a lower current density compared to prior art SOFCs, and since polarization losses increase with current density the net polarization losses are less. Conversely, micro-featured cells 110 can be targeted for higher power than is possible with current micro-planar SOFC cells 10 at similar polarization losses.

After the bi-layer laminate is featured and fired in accordance with the invention, additional layers such as cathode layer 16 must be applied. To keep layers at functionally optimal thicknesses, it is important that such layers be applied using a method that creates a consistent thickness on the micro-dimpled surface. A prior art application process such as screen printing tends to fill the micro-dimples, creating increased ohmic polarization as well as concentration polarization due to the increased thickness of the cathode layer film at the micro-dimples. Therefore, instead of screen printing, a method for applying additional layers may be spray coating, including for example electrostatic, pressure spray, laser-assisted chemical vapor synthesis methods, chemical vapor deposition, and physical vapor deposition. Each of these methods applies uniform layers that can take advantage of the micro-dimpled bi-layer construction. The final conductive Ag/Pd layer (not shown) on the cathode side of the cell may also be applied via spray technique in order to create a uniform thickness over the micro-dimpled surface of the formed cathode layer.

The foregoing discussion is directed toward a planar fuel cell. However, in the broader sense the present invention may be directed to any form of fuel cell wherein the surface area of the laminate is increased by creation of features in the surface. Thus, other fuel cell forms such as cylinders, and other features of any kind besides spherical dimples, are fully anticipated by the present invention. The dimples of the present discussion are employed by example, for purposes of discussion, because the surface area improvements are readily calculable from geometric considerations, but such dimples may not in fact be the area-increasing features of choice in any particular application.

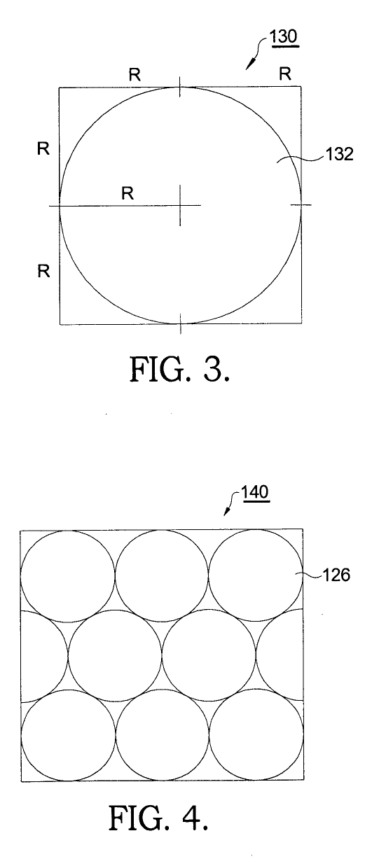

Referring now to FIG. 3, the potential increase in surface area in a dimple pattern over a surface area without dimples can be seen. Consider a planar area of a portion of a cell such as cell portion 130 without dimples having dimensions 2R×2R, and an area 4R². Consider also a dimple 132 formed inside this area having a radius equal to R and inserted R deep into cell portion 130 (fully hemispherical). The surface area of the formed dimple itself is 2πR². The plan surface area of cell portion 130, with a formed dimple, therefore equals 4R²−πR² (the area of the circle occupied by the dimple)+2πR², or 4R²+πR². Thus, assuming π to be equal to 3.14, the surface area of cell 130, shown in FIG. 3 with a formed dimple of cell portion 130 equals 7.14 R², and the ratio of surface areas after dimple formation compared to the non-dimpled original surface area equals 7.14 R²/4R², or 1.785. In other words, a full insertion dimpling in a rectangular dimple array as shown in FIG. 2 produces about a 78.5% increase in surface area as compared to a prior art non-dimpled planar surface of the same rectangular size. Of course, any reduction from a hemispherical R insertion depth of the dimple, while still beneficial, leads to a somewhat diminished surface area improvement over full insertion dimpling.

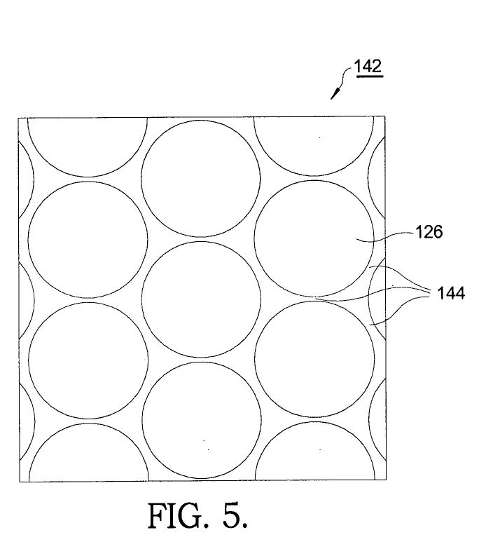

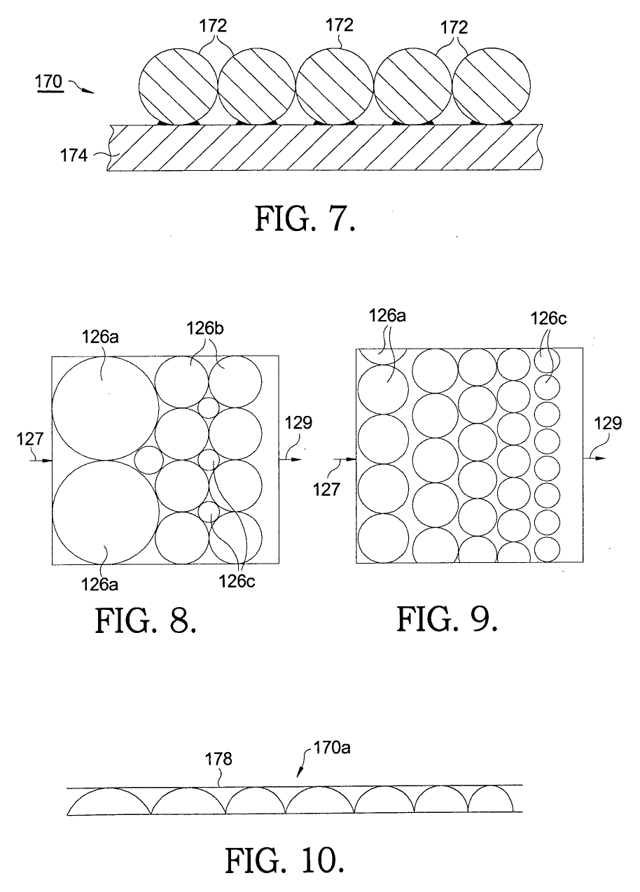

In another example, referring to FIG. 4, a hexagonal close-spaced array 140 (with six surrounding dimples touching a central dimple) yields a surface area improvement of about 90% for full R insertion depth as compared to a prior art planar design surface area. As defined herein, when the dimples are touching at the undeformed surface of the bi-layer laminate as shown in FIG. 4, the dimples are said to be close-spaced. As shown in FIG. 5, the hexagonal array 142 may also be formed by partial hemispherical R insertion depth of bilayer against the ball indenter array shown in FIG. 7. At present, hexagonal array 142 with less than hemispherical R ball insertion is preferred over a full R insertion depth since such an array has less localized strain due to consistent, gradual lead-in from undeformed region to dimples. Since the dimples in FIG. 5 are not touching at the undeformed surface of the bi-layer laminate, the dimples are said to be non-close-spaced.

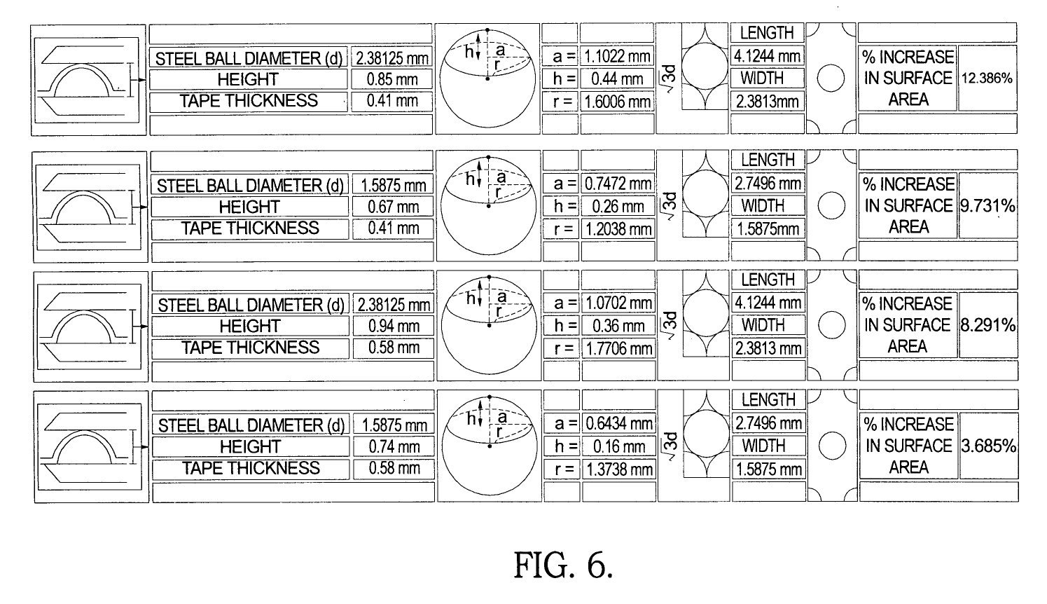

FIG. 6 shows surface area increases in exemplary trials using two different indenter ball diameters and two different anode laminate (“tape”) thicknesses and using 3,500 psi isostatic pressure to mold the pieces. Note that surface area can be increased by decreasing laminate thickness, such as by reducing a prior art standard laminate thickness that incorporates three layers to a thinner laminate having two bulk anode layers. The corresponding reduction in required anode material is an important benefit of the present invention. For example, using a 2.38 mm ball, a prior art green laminate tape 18 (FIG. 1) having a thickness of 0.58 mm with three layers 12a,12b,12c of bulk anode 12 showed an increased surface area of 8.3%. For the same diameter ball, an improved green laminate tape having a reduced thickness of 0.41 mm with two layers of bulk anode (savings of 29% in anode material) showed a surface area increase of approximately 12.4%.

Further, at constant pressure as indenter ball diameter is increased, for example, from 1.58 mm to 2.38 mm at a constant laminate thickness of 0.41 mm, surface area is increased from 9.73% to 12.86%. Thus, surface area improvements on the order of about 3% to 12% are readily achievable in accordance with the present invention, depending upon ball diameter and laminate thickness.

Note that, with increasing pressure, the degree of indentation increases, leading to increased surface area. If the pressure is increased to achieve a certain degree of indentation for various indenter ball diameters, then surface area may be increased using smaller dimples. Thus, surface area improvements may be achievable by increasing pressure so that smaller indenter diameters and thin tape may be preferred.

Referring to FIG. 7, in one aspect of the invention, dimples are imparted into an unfired bi-layer laminate by using a profiled stainless steel indenter plate 170 during an isostatic lamination process. An isostatic pressure of about 3,500 psi is applied to the green bi-layer laminate, for example by a hydraulic cushion (not shown) behind a flexible hydraulic membrane in full contact with the opposite side of the laminate and opposing a backing plate 170 with force sufficient to cause the bi-layer laminate to take the shape of the balls 172 on the profiled backing plate 170. Plate 170 may be readily formed by welding of an appropriately-shaped array of steel balls 172 onto a backer 174. Of course, other means for imparting a ball pattern will be obvious to those of ordinary skill in the forming arts, such as for example by attaching balls to the outer surface of a roller (not shown) for rolling over the green bi-layer laminate. Preferably, the thick anode side of the unfired bi-layer laminate is placed against the profiled backing plate to limit the potential for electrolyte damage from foreign particles that could be on the steel balls 172.

Stainless steel balls may be resistance welded to a stainless steel plate to create profiled lamination backing plate 170. However, it will be obvious to those of ordinary skill in the art that profiled backing plates may be fabricated by many available methods, for example, by stamping (which may be preferred for larger quantities) or by chemical etching.

After dimpling, the micro-dimpled green bi-layer laminate is fired to create a dense electrolyte. It has been found that the dimples may be easily maintained during firing when the green laminate is supported on a conventional alumina-silicate setter without any other constraint.

Because fuel is consumed as it traverses across a fuel cell surface, there is consequently a gradual reduction in available reacting species, leading to increasing concentration-related polarization losses across the cell in the direction of fuel flow. This also leads to ohmic polarization due to uneven current flow through the various functional layers.

To accommodate the gradual reduction in available reacting species, a fuel cell having a variably textured surface may be used in accordance with the invention. FIG. 8 shows an example of this approach wherein large size dimples 126a are used near the fuel inlet 127 and transition to smaller dimples 126b, with interstitial dimples 126c near the fuel exit 129. Such dimple size gradation creates a surface area gradient such that surface area increases as fuel concentration decreases, resulting in more even current flow through the various functional layers.

FIG. 9 shows a textured fuel cell having large diameter dimples 126a near the fuel inlet 127 and transitioning in diameter to increasing numbers of small dimples 126c near the fuel exit 129. Of course other approaches are possible within the scope of the present invention such as by varying shape of texture, frequency of texture, texture pattern, height of pattern, and numerous other known methods. The features need not be hemisperical but may take any desired form of upset from a planar bi-layer.

FIG. 10 shows an elevation cross-section of an indenter backing plate array 170a used to create a bi-layer having varying surface area in the direction of fuel flow. Note that it is generally desirable to have the top of the various diameter indenter shapes lie along the same plane 178, which allows for simple interconnection using Ag/Pd paste to the next SOFC repeating unit. It is generally desirable that the bottom of the textured cell have a common bottom-most plane feature, which can be achieved by using a varying-size indenter backing plate with similar depth hollows, as is shown in FIG. 10. The varying size indenter backing plate can be made by casting, chemical etching, or by welding various shapes to a planar backer plate.

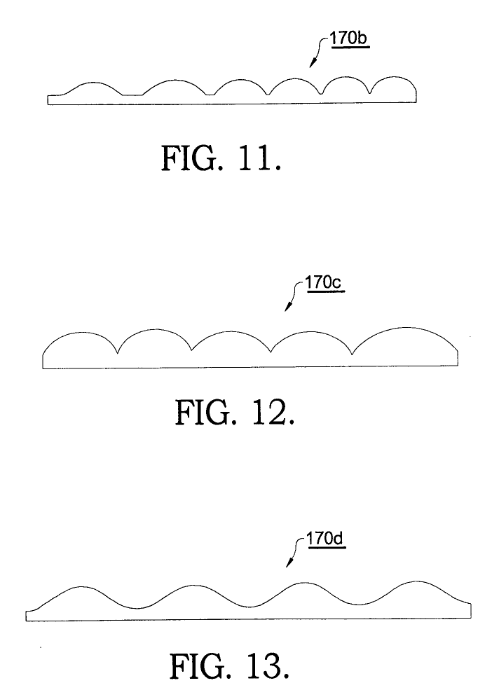

Some other exemplary possible indenter backing plate profiles are shown in FIGS. 11 through 13.

FIG. 11 shows a featured backing plate 170b for forming a featured bi-layer laminate having non-close-spaced dimple features of differing radius and equal depth, and also having flat regions between the dimples.

FIG. 12 shows a featured backing plate 170c for forming a featured bi-layer laminate having close-spaced dimple features of differing radius and equal depth; and

FIG. 13 shows a featured backing plate 170d for forming a featured b-layer laminate having a sinusoidally-varying surface.

In accordance with the present invention, degree of indenter insertion and dimple height may be varied areally across a fuel cell as may be needed to balance, for example, fuel utilization to improve overall fuel cell efficiency.

A textured bi-layer laminate such as laminate 142 shown in FIG. 5 has increased moment of inertia compared to the prior art micro and macro planar fuel cell design since there are no possible stress fields that can transfer through the laminate without encountering dimples. As a result of this structural reinforcement, it becomes possible for a micro-dimpled fuel cell to have greater bending resistance than that of a prior art non-dimpled planar cell.

The high-low pattern established by the textured fuel cell also offers a further benefit with respect to repeating cells in a fuel stack in that the textured structure eliminates the need for a separate interconnect structure on the raised dimple side of the cell. Accordingly, each cell formed in accordance with the invention may have a conductive paste dispensed onto the tops of some or all of the dimples. Those dimples may then be attached directly and rigidly to a separator plate of the next repeating unit. On the surface of the cell opposite the protruding dimples which defines the hollows of the dimples, a flexible interconnect material may be utilized to take up any movement induced by a mismatch of thermal coefficients of expansion. The interconnect may be formed, for example, as a mesh, a thin formed convoluted interconnect, or any other known flexible interconnect. In the prior art, the cathode interconnect is typically formed of a relatively expensive silver-coated Kanthal mesh, while the anode interconnect is typically formed of a less expensive nickel alloy. Then, since the interconnects are flexible, a Ag/Pd paste is necessarily applied to each of the interconnects to assure a good electrical connection with the interconnects. Since the separate flexible cathode interconnect is no longer needed in accordance with the invention, the silver-coated Kanthal mesh interconnect and the amount of Ag/Pd paste used to assure a good electrical connection with the flexible cathode interconnect may be eliminated.

The textured fuel cell when integrated into a repeating unit must be amenable to being sealed so that anode gas is maintained separate from cathode gas. This is preferably achieved by forming the cell having a non-dimpled border region within about 5 mm of the perimeter. The height of this non-dimpled region can be adjusted relative to the height of the dimpled region as desired. Height of the non-dimpled region and the lack of dimples in that region are readily provided by the profile of the backing plate used during isostatic lamination.

Within the scope of the present invention, variations on the above arrangement are comprehended. For example, a wire mesh may be used instead of steel balls to impart features to the anode and cathode surfaces.

Alternatively, a sinusoidal type of surface may be produced using two opposed profiled backing plates which may eliminate the need for any flexible interconnects within each repeating fuel cell unit since dimples are formed on both sides of the cell. Similarly, the green bi-layer laminate my be pressed between opposed and interlocking profiled backing plates 170 such that interlocking dimple patterns are formed with both bumps and hollows on both sides of the laminate. A sinusoidally or bi-directionally dimpled cell may nearly double the surface area of the single protruding dimple arrangement and may be used with a flexible interconnect on one side of the cell. Alternatively, a less-rigid seal material may be used to provide some movement between cells or components in a fuel cell stack. In addition, this arrangement provides equal exposure to gases on each side, which can result in more equalized reaction rates.

While the invention has been described by reference to various specific embodiments, it should be understood that numerous changes may be made within the spirit and scope of the inventive concepts described. Accordingly, it is intended that the invention not be limited to the described embodiments, but will have full scope defined by the language of the following claims.

What is claimed is:

1. A fuel cell comprising an anode layer, an electrolyte layer, and a cathode layer,
wherein at least one of said anode layer and said cathode layer has an outer surface, and
wherein said outer surface includes a plurality of textural features extending in at least one direction from said outer surface, such that the effective area of such texturally-featured outer surface is greater than the surface area of a comparable non-featured surface.

2. A fuel cell in accordance with claim 1 wherein said electrolyte layer is formed of ceramic, and wherein said fuel cell is a solid oxide fuel cell.

3. A fuel cell in accordance with claim 1 wherein said textural features extend outward of said surface of said anode layer and inward said surface of said cathode layer.

4. A fuel cell in accordance with claim 1 wherein said textural features extend inward of said surface of said anode layer and outward of said surface of said cathode layer.

5. A fuel cell in accordance with claim 1 wherein said textural features are spherical.

6. A fuel cell in accordance with claim 5 wherein the diameter of said spherical features is between about 1.5 mm and about 2.5 mm.

7. A fuel cell in accordance with claim 1 wherein the shape of said fuel cell is selected from the group consisting of planar and tubular.

8. A fuel cell in accordance with claim 1 wherein said textural features are arranged in at least one geometric array.

9. A fuel cell in accordance with claim 8 wherein said array is selected from the group consisting of rectangular and hexagonal.

10. A fuel cell in accordance with claim 8 wherein said array is arranged to influence gas flow along said texturally-featured surface.

11. A fuel cell in accordance with claim 10 wherein said texturally-featured surface includes greater surface area near a fuel exit of said fuel cell as compared to surface area near a fuel inlet thereof.

12. A fuel cell in accordance with claim 11 wherein larger size features are provided near said fuel inlet, and wherein smaller size features are provided near said fuel exit.

13. A fuel cell in accordance with claim 12 wherein interstitial features are provided between said larger size features and said smaller size features.

14. A fuel cell in accordance with claim 8 wherein said array is formed by pressing a featured backing plate against at least said anode layer during manufacture of said fuel cell.

15. A fuel cell in accordance with claim 1 wherein at least some of said outward extending textural features are capable of forming electrical contact with an adjacent fuel cell in a stack formed of a plurality of said fuel cells.

16. A fuel cell in accordance with claim 1 wherein the thickness of said anode layer and said electrolyte layer is about 0.41 mm.

17. A method for forming a fuel cell having an anode layer and an electrolyte layer including the steps of:
a) forming a laminate of said anode layer and said electrolyte layer;
b) pressing a featured backing plate against one side of said laminate to form textural features therein; and
c) curing said laminate.

18. A method in accordance with claim 17 including the further step of forming a cathode layer in contact with said electrolyte layer after said curing step.

19. A method in accordance with claim 18 wherein said step of forming said cathode layer is carried out by spray coating.

20. A method in accordance with claim 19 wherein a technique for said spray coating is selected from the group consisting of electrostatic spray, pressure spray, laser-assisted chemical vapor synthesis, chemical vapor deposition, and physical vapor deposition.

21. A method in accordance with claim 17 wherein said featured backing plate is a first featured backing plate, the method comprising the step of simultaneously pressing a second featured backing plate against the side of said laminate opposite said first featured backing plate.

22. A method in accordance with claim 21 wherein said first and second featured backing plates are provided with interlocking features such that after said pressing step said laminate includes features extending outward from both sides thereof.
